(19) United States
(12) Patent Application Publication
(10) Pub. No.: US 2010/0133652 A1
(43) Pub. Date: Jun. 3, 2010

(54) Semiconductor device and method of manufacturing the same

(75) Inventor: Takao Atsumo, Kanagawa (JP)

Correspondence Address: MCGINN INTELLECTUAL PROPERTY LAW GROUP, PLLC, 8321 OLD COURTHOUSE ROAD, SUITE 200, VIENNA, VA, 22182-3817, US

(73) Assignee: NEC ELECTRONICS CORPORATION, Kawasaki (JP)

(21) Appl. No.: 12/591,728

(22) Filed: Nov. 30, 2009

(30) Foreign Application Priority Data
Dec. 3, 2008 (JP) 2008-308129

(51) Int. Cl. H01L 29/86; H01L 21/02

(52) U.S. Cl. 257/531; 438/393; 257/532; 257/E21.008; 257/E21.022; 438/381; 257/E29.325; 257/528

(57) ABSTRACT

Provided is a semiconductor device capable of increasing the capacitance of a capacitor, while reducing an area occupied by the capacitor and inductor on a substrate. The semiconductor device includes a first line; an interlayer insulating film that is formed on the first line and has a recess formed at a location corresponding to the first line; and a second line formed in the recess of the interlayer insulating film. The first line, the second line, and an insulating film formed between the first line and the second line constitute a capacitor. At least one of the first line and the second line constitutes an inductor.

### BACKGROUND

1. Field of the Invention

The present invention relates to a semiconductor device and a method of manufacturing the same. In particular, the present invention relates to a high-frequency semiconductor device including an inductor and a capacitor.

2. Description of Related Art

In recent years, downsizing and high integration of semiconductor devices typified by a monolithic microwave integrated circuit (MMIC) or the like have progressed. In particular, passive elements such as lines and inductors which constitute each semiconductor device occupy a large area on the semiconductor device. Accordingly, further downsizing and higher integration of passive elements, such as lines and inductors, are demanded.

Japanese Unexamined Patent Application Publication Nos. 2006-245273 and 2004-304183 disclose a technique for reducing an area occupied by inductors when the inductors are formed on a semiconductor substrate. FIGS. 11A and 11B are explanatory diagrams showing the inductors disclosed in Japanese Unexamined Patent Application Publication No. 2006-245273. The inductors disclosed in Japanese Unexamined Patent Application Publication No. 2006-245273 include a spiral transmission line 11 of a first layer, a transmission line 12 of a second layer, and a spiral transmission line 13 of a third layer. An output part of the transmission line 11 is connected to an input part of the transmission line 12 at a node con1. A first output part of the transmission line 12 is connected to an input part of the transmission line 13 at a node con2. A second output part of the transmission line 12 is connected to one terminal of a capacitor 15, which is formed on the semiconductor substrate, at a node con4.

### SUMMARY

The present inventor has found a problem as described below. Reference is now given to FIG. 9 which is a circuit diagram showing two inductor circuits having two inductors that are connected in series are connected with a capacitor at each node of the two inductors. FIG. 10 shows the configuration of a device for realizing in practice the circuit shown in FIG. 9. An inductor+capacitor part shown in FIG. 10 includes a lower layer line 23 and an upper layer line 24. Each of the lower layer line 23 and the upper layer line 24 constitutes a spiral inductor. These lines are formed on a substrate 21. Further, an interlayer insulating film 22 is formed between the lower layer line 23 and the upper layer line 24. The lower layer line 23, the interlayer insulating film 22, and the upper layer line 24 constitute an MIM capacitor. Also in a wiring part, a lower layer line 25 and an upper layer line 26 are formed. Even in the circuit configuration including the spiral inductors and the MIM capacitor, it is necessary to minimize the area of the layout.

Referring to FIG. 10, in order to increase the capacitance of the capacitor which is composed of the lower layer line 23, the interlayer insulating film 22, and the upper layer line 24, the thickness of the interlayer insulating film 22 needs to be reduced. When the interlayer insulating film 22 is reduced in thickness, however, the distance between the lower layer line 25 and the upper layer line 26 is also reduced in the wiring part. This results in an increase in parasitic capacitance which is generated between the lower layer line 25 and the upper layer line 26.

On the other hand, as disclosed in Japanese Unexamined Patent Application Publication No. 2006-245273, the capacitor 15 is formed in a region other than the region of the lines 11 and 13 each constituting a spiral inductor (i.e., a region which does not overlap the region of the lines 11 and 13 when viewed in the direction vertical to the substrate surface). As a result, the capacitance of the capacitor can be increased without reducing the thickness of the interlayer insulating film 22. In this case, however, there arises a problem in that when the capacitor is formed in a region other than the region of the inductor lines, the area occupied by the capacitor and inductor on the substrate is increased.

A first exemplary aspect of the present invention is a semiconductor device including: a first line; an interlayer insulating film that is formed on the first line and has a recess formed at a location corresponding to the first line; and a second line formed in the recess of the interlayer insulating film. The first line, the second line, and an insulating film formed between the first line and the second line constitute a capacitor, and at least one of the first line and the second line constitutes an inductor.

With the above-mentioned configuration, the distance between the first line and the second line, which constitute the capacitor, can be reduced, thereby making it possible to increase the capacitance of the capacitor. Moreover, the capacitor and inductor can be formed in a region in which the capacitor and inductor overlap each other when viewed in the direction vertical to the substrate surface, which results in a reduction in the area occupied by the capacitor and inductor on the substrate.

A second exemplary aspect of the present invention is a method of manufacturing a semiconductor device including: forming a first line on a substrate; forming an interlayer insulating film on the first line; and forming a second line on the interlayer insulating film. In the method of the second exemplary aspect of the invention, the interlayer insulating film has a recess formed at a location corresponding to the first line. Further, the first line, the second line, and an insulating film formed between the first line and the second line constitute a capacitor. Furthermore, at least one of the first line and the second line constitutes an inductor.

With the above-mentioned manufacturing method, the distance between the first line and the second line, which constitute the capacitor, can be reduced, thereby making it possible to increase the capacitance of the capacitor. Moreover, the capacitor and inductor can be formed in a region in which the capacitor and inductor overlap each other when viewed in the direction vertical to the substrate surface, which results in a reduction in the area occupied by the capacitor and inductor on the substrate.

According to exemplary embodiments of the present invention, it is possible to increase the capacitance of the capacitor, while reducing the area occupied by the capacitor and inductor on the substrate.

### BRIEF DESCRIPTION OF THE DRAWINGS

The above and other exemplary aspects, advantages and features will be more apparent from the following description of certain exemplary embodiments taken in conjunction with the accompanying drawings, in which:

FIG. 1 is a sectional view showing a semiconductor device according to a first exemplary embodiment of the present invention;

FIG. 2A is a plan view showing a layout example of a lower layer line of the semiconductor device according to the first exemplary embodiment;

FIG. 2B is a plan view showing a layout example of an upper layer line of the semiconductor device according to the first exemplary embodiment;

FIG. 2C is a plan view showing a layout example of the lower layer line and upper layer line of the semiconductor device according to the first exemplary embodiment;

FIG. 3 is a graph showing the relationship between the S-parameters and frequency of the semiconductor device according to the first exemplary embodiment;

FIG. 4 is a graph showing the relationship between the inductance and frequency of the semiconductor device according to the first exemplary embodiment;

FIG. 5 is a diagram for explaining a method of calculating an inductance from S-parameters;

FIG. 6 is a sectional view showing a semiconductor device according to a second exemplary embodiment of the present invention;

FIG. 7 is a sectional view showing a semiconductor device according to a third exemplary embodiment of the present invention;

FIG. 8 is a sectional view showing a semiconductor device according to a fourth exemplary embodiment of the present invention;

FIG. 9 is an equivalent circuit diagram showing inductors and a capacitor;

FIG. 10 is a diagram for explaining a problem of the present invention; and

FIGS. 11A and 11B are diagrams for explaining the background of the present invention.

### DETAILED DESCRIPTION OF THE EXEMPLARY EMBODIMENTS

### First Exemplary Embodiment

A first exemplary embodiment of the present invention will be described below with reference to the accompanying drawings.

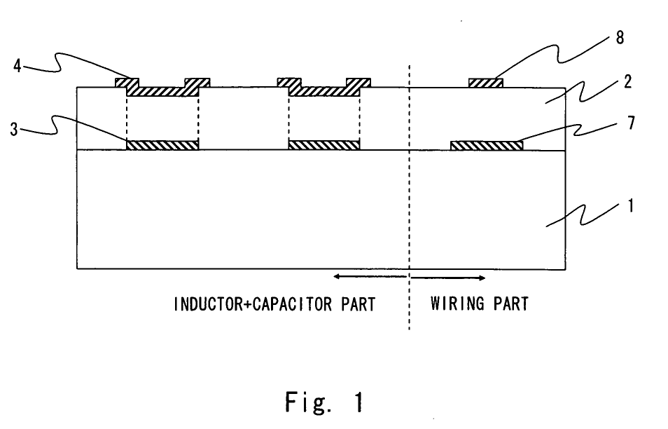

FIG. 1 is a sectional view showing a semiconductor device according to this exemplary embodiment. The semiconductor device according to this exemplary embodiment includes a lower layer line 3 (first line) formed on a substrate 1, an interlayer insulating film 2, and an upper layer line 4 (second line). The interlayer insulating film 2 is formed on the lower layer line 3 and has a recess formed at a location corresponding to the lower layer line 3. The upper layer line 4 is formed in the recess of the interlayer insulating film 2. The lower layer line 3, the upper layer line 4, and an insulating film formed between the lower layer line 3 and the upper layer line 4 (the interlayer insulating film 2) constitute a capacitor. Further, at least one of the lower layer line 3 and the upper layer line 4 constitutes an inductor.

In the semiconductor device of this exemplary embodiment, a recess is formed at a location corresponding to the lower layer line 3 of the interlayer insulating film 2. In this case, the term “location corresponding to the lower layer line 3” refers to a location which overlaps the lower layer line 3 when viewed in the direction vertical to the substrate surface. As long as the capacitance of the capacitor, which is composed of the lower layer line 3, the upper layer line 4, and the interlayer insulating film 2, increases as the distance between the lower layer line 3 and the upper layer line 4 decreases, the recess formed in the interlayer insulating film 2 may have a width larger or smaller than the width of the lower layer line 3.

With the above-mentioned configuration, the distance between the first line and the second line, which constitute the capacitor, can be reduced, thereby making it possible to increase the capacitance of the capacitor. In addition, the capacitor and the inductor can be formed in a region in which the capacitor and inductor overlap each other when viewed in the direction vertical to the substrate surface, which results in a reduction in the area occupied by the capacitor and inductor on the substrate.

Further, the semiconductor device of this exemplary embodiment includes an inductor+capacitor part as well as a wiring part. The wiring part includes a lower layer line 7 (third line) formed on the substrate 1, the interlayer insulating film 2 formed on the lower layer line 7, and an upper layer line 8 (fourth line) formed on the interlayer insulating film 2.

In the semiconductor device of this exemplary embodiment, the recess is formed only in the interlayer insulating film of the inductor+capacitor part. With this configuration, the distance between the lower layer line 3 and the upper layer line 4 of the inductor+capacitor part can be reduced without changing the distance between the lower layer line 7 and the upper layer line 8 of the wiring part. As a result, the capacitance of the capacitor can be increased without increasing a parasitic capacitance which is generated between the lower layer line 7 and the upper layer line 8.

Furthermore, in the semiconductor device of this exemplary embodiment, at least one of the lower layer line 3 and the upper layer line 4 constitutes an inductor. In other words, both the lower layer line 3 and the upper layer line 4 may constitute the inductor, or either one of the lower layer line 3 and the upper layer line 4 may constitute the inductor. The lower layer line is usually formed with a thickness smaller than that of the upper layer line, because the interlayer insulating film is formed on the lower layer line. In this case, the upper layer line 4 has a resistance smaller than that of the lower layer line 3. Accordingly, in the semiconductor device of this exemplary embodiment, the upper layer line 4 may preferably be used as the inductor.

Examples of the inductor of the semiconductor device according to this exemplary embodiment include a spiral inductor which is a line formed in a spiral manner, and a meander inductor which is a line formed in the shape of meander. Note that in the semiconductor device of this exemplary embodiment, the shape of the lines is not limited to the spiral shape and the meander shape, as long as the lines are arranged so as to function as inductors.

The lower layer line 3 and the upper layer line 4 shown in FIG. 1 can be formed using, for example, WSi, TiN, Pt, Au, Ti, Al, or Cu, or an alloy or a laminate structure of an arbitrary combination of these metals. The interlayer insulating film 2 can be formed using, for example, SiO₂ or SiN. The substrate 1 can be formed using, for example, GaAs or Si.

The above-mentioned materials for forming the semiconductor device are illustrative only, and can be arbitrarily selected as long as the effects according to an exemplary embodiment of the present invention are exhibited.

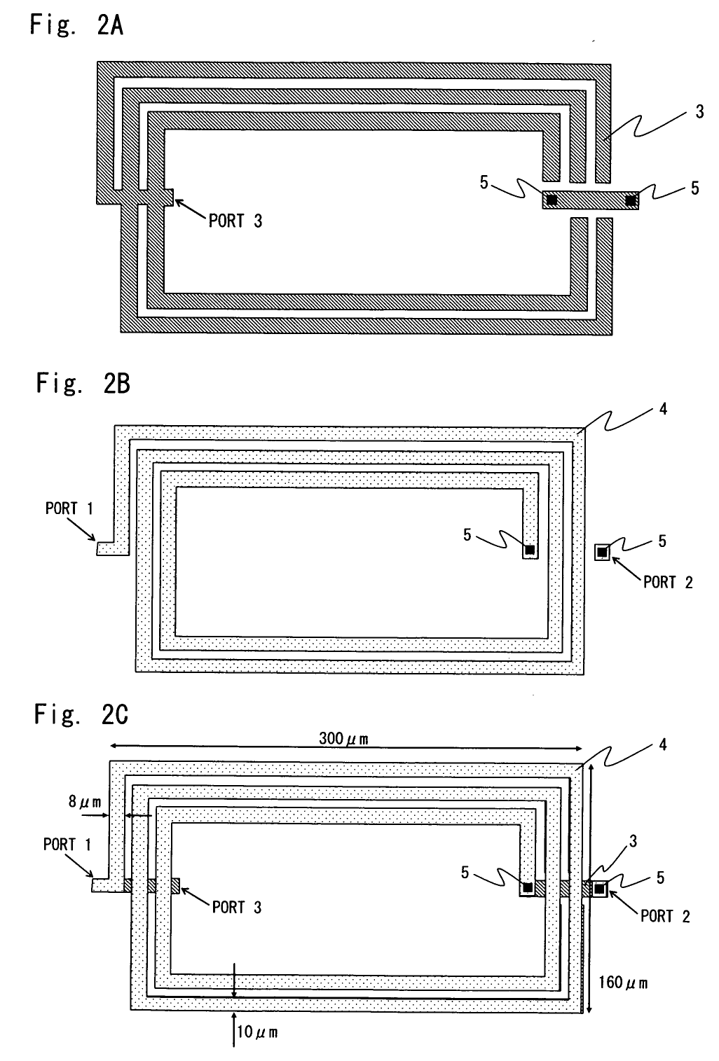

Next, as an example of the semiconductor device according to this exemplary embodiment, FIG. 2 shows an example in which the spiral inductor is composed of the upper layer line 4, and the capacitor is composed of the lower layer line 3, the interlayer insulating film 2, and the upper layer line 4. FIG. 2A is a diagram showing a pattern of the lower layer line 3. FIG. 2B is a diagram showing a pattern of the upper layer line 4. FIG. 2C is a diagram showing a state where the lower layer line 3 and the upper layer line 4 overlap each other.

The spiral inductor of the semiconductor device according to this exemplary embodiment is composed of the upper layer line 4 shown in FIG. 2B. One end of the spiral inductor is connected to another circuit through a port 1. The other end of the spiral inductor is connected to another circuit through a port 2. The other end of the spiral inductor is connected to the lower layer line through a via 5, and the lower layer line is connected to the upper layer line having the port 2 through the via 5.

The capacitor of the semiconductor device according to this exemplary embodiment is composed of the lower layer line 3 shown in FIG. 2A, the upper layer line 4 shown in FIG. 2B, and the interlayer insulating film. In this case, when the patterns of the lower layer line and the upper layer line are formed so as to match as closely as possible, the capacitance of the capacitor increases. Referring to FIG. 2A, the pattern of the lower layer line is formed so as not to be brought into contact with the line having the via 5.

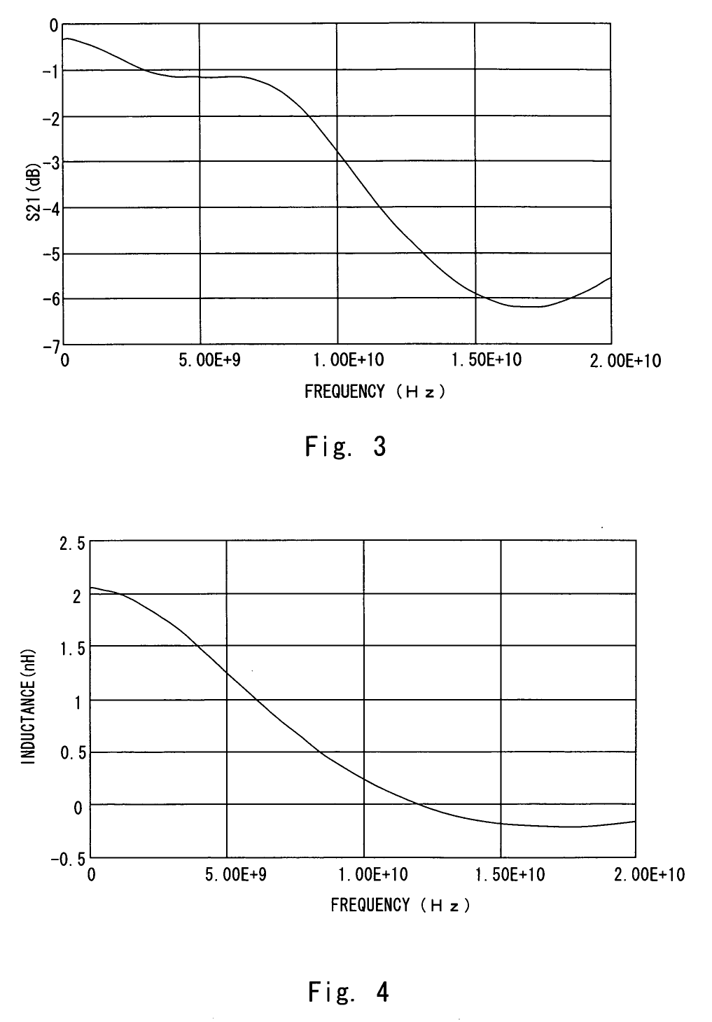

Reference is now given to FIGS. 3 and 4 which respectively show calculation results of the relationship between the S-parameters and frequency characteristics and calculation results of the relationship between the inductance and frequency characteristics, respectively, when the semiconductor device of this exemplary embodiment has a cross-sectional structure shown in FIG. 1 and a wiring layout shown in FIGS. 2A to 2C. A 2.5-dimensional electromagnetic simulator was used for the calculation. The inductance is a value calculated from the S-parameters. The circuit according to this exemplary embodiment functions as a so-called low-pass filter including a capacitor and an inductor. The simulation results of FIGS. 3 and 4 show the characteristics in which the S-parameters and the inductance are hardly reduced in a low-frequency region and are greatly reduced in a high-frequency region.

In this case, it is assumed that the width of each of the lower layer line 3 and the upper layer line 4 shown in FIG. 1 is 10 μm, and the thickness of the lower layer line 3 is, for example, 0.7 μm. It is also assumed that the distance between the upper surface of the lower layer line 7 and the surface of the interlayer insulating film 2 in the wiring part is 0.8 μm, and the combined thickness of the substrate 1 and the interlayer insulating film 2 is 50 μm. Further, as shown in FIG. 2C, the lines are formed with a layout of 300 μm×160 μm, and the widths of the lines are 8 μm and 10 μm, respectively.

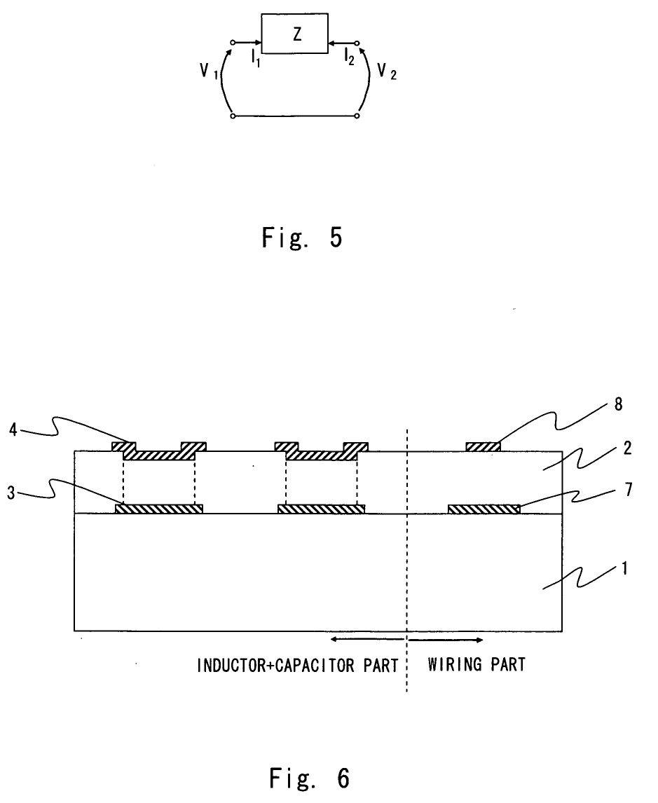

The method of calculating the inductance from the S-parameters is shown below. In a two-terminal pair circuit in which an impedance Z is connected in series as shown in FIG. 5, the impedance is calculated as follows. First, when the voltage and current at the primary-side and the voltage and current at the secondary-side are defined as shown in FIG. 5, the following is given by Kirchhoff's laws.

$${I}_{1} = \frac{{V}_{1} - {V}_{2}}{Z} , \\ {I}_{2} = \frac{{V}_{2} - {V}_{1}}{Z} \qquad ( 1 )$$

When the equation is represented in matrix form, the following equation is obtained.

$$( \begin{matrix}{I}_{1} \\ {I}_{2}\end{matrix} ) = \frac{1}{Z} ( \begin{matrix}1 & - 1 \\ - 1 & 1\end{matrix} ) ( \begin{matrix}{V}_{1} \\ {V}_{2}\end{matrix} ) \qquad ( 2 )$$

On the other hand, the following equation is obtained based on the definition of Y-parameters.

$$( \begin{matrix}{I}_{1} \\ {I}_{2}\end{matrix} ) = ( \begin{matrix}{Y}_{11} & {Y}_{12} \\ {Y}_{21} & {Y}_{22}\end{matrix} ) ( \begin{matrix}{V}_{1} \\ {V}_{2}\end{matrix} ) \qquad ( 3 )$$

When the both elements of the matrix on the right side are compared, the following equation can be obtained.

$${Y}_{12} = {Y}_{21} = - \frac{1}{Z} \qquad ( 4 )$$

Assuming that Z represents a series of inductors, Z=jωL, is satisfied, and the following equation can be obtained.

$${Y}_{12} - {Y}_{21} -- \frac{1}{j ω L} \qquad ( 5 )$$

Accordingly, the following equation can be derived.

$$L = - Im ( \frac{1}{ω {Y}_{12}} ) = - Im ( \frac{1}{2 π f \cdot {Y}_{12}} ) \qquad ( 6 )$$

In this case, the Y-parameters can be obtained using the S-parameters.

In the semiconductor device of this exemplary embodiment, the distance between the lower layer line 3 and the upper layer line 4, which constitute the capacitor, can be reduced, thereby making it possible to increase the capacitance of the capacitor. Further, the capacitor and inductor can be formed in the region in which the capacitor and inductor overlap each other when viewed in the direction vertical to the substrate surface, which results in a reduction in the area occupied by the capacitor and inductor on the substrate.

### Second Exemplary Embodiment

A second exemplary embodiment of the present invention will be described below with reference to FIG. 6. Note that components similar to those of the first exemplary embodiment shown in FIG. 1 are denoted by the same reference numerals, and repeated description thereof is omitted.

In this exemplary embodiment, the lower layer line 3 has a width greater than that of the first exemplary embodiment. That is, in the semiconductor device of this exemplary embodiment, the width of the lower layer line 3 is set to be greater than the width of the recess formed in the interlayer insulating film 2 (i.e., the width of a space in which the upper layer line 4 is filled) as shown in FIG. 6. With this configuration, even when a machining error is produced in the case of forming the lower layer line 3 and the recess of the interlayer insulating film 2, the areas of opposed electrodes (i.e., the lower layer line 3 and the upper layer line 4) can be made uniform. As a result, the capacitance of the capacitor can be made constant. While description has been made of the case where the lower layer line 3 has a width greater than the width of the upper layer line 4 as shown in FIG. 6, the same effects can be obtained even when the width of the upper layer line 4 is set to be greater than the width of the lower layer line 3 in this exemplary embodiment. In this case, a recess having a width greater than the width of the lower layer line 3 is formed in the interlayer insulating film 2, and the upper layer line 4 is filled in the recess thus formed.

### Third Exemplary Embodiment

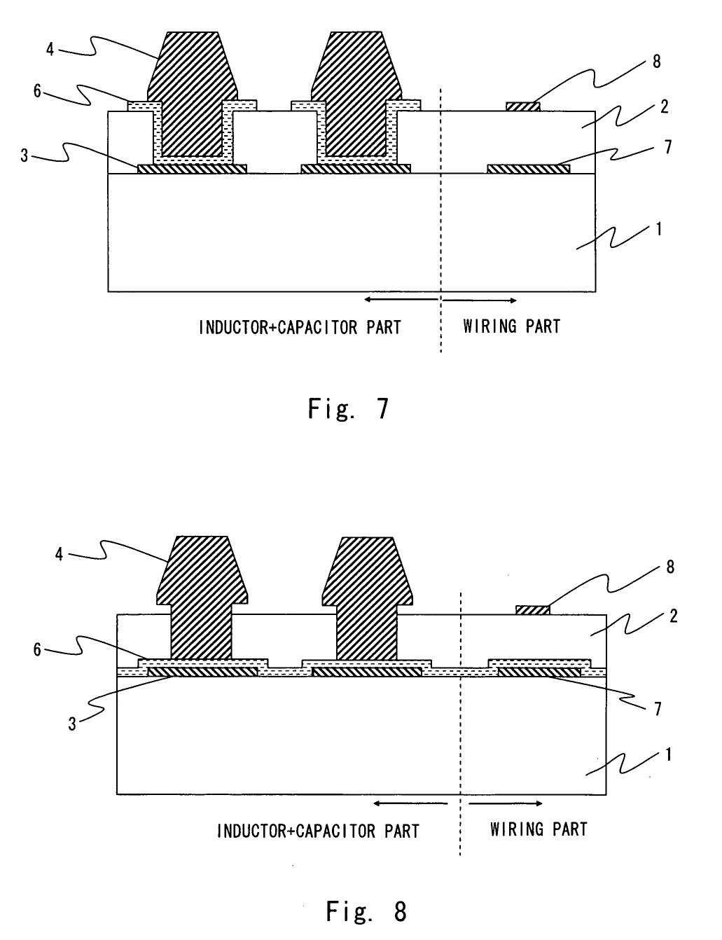

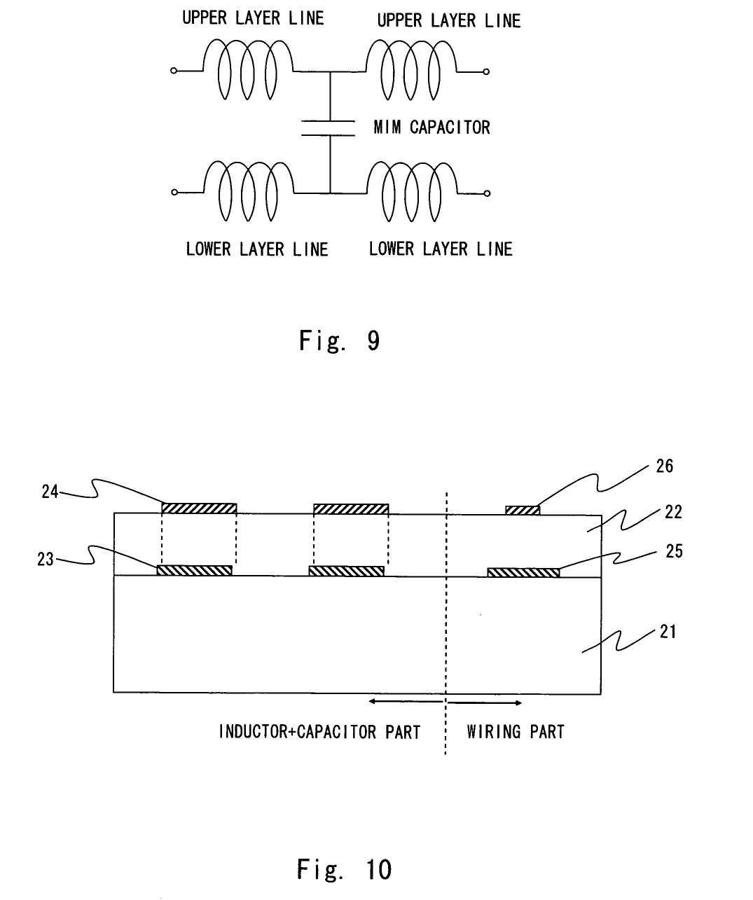

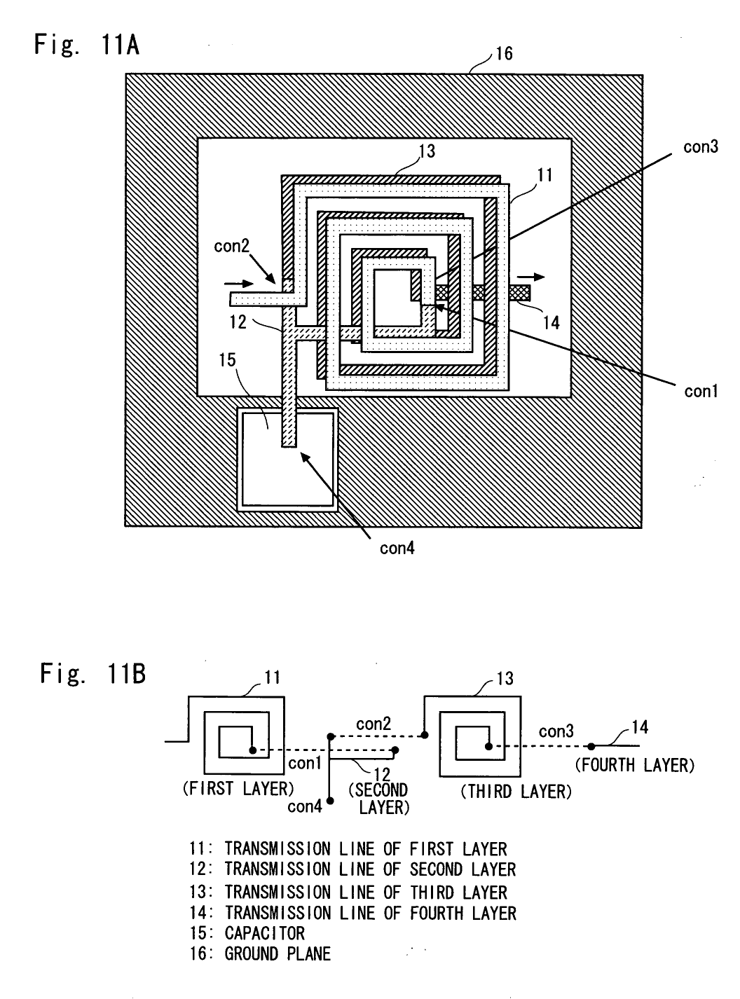

A third exemplary embodiment of the present invention will be described below with reference to FIG. 7. Note that components similar to those of the first exemplary embodiment shown in FIG. 1 are denoted by the same reference numerals, and repeated description thereof is omitted.

In this exemplary embodiment, an insulating film 6, which is different from the interlayer insulating film 2, is used as an insulating film for forming a capacitor.

In this exemplary embodiment, when a recess is formed in the interlayer insulating film 2 after the formation of the lower layer line 3, the recess is formed so as to reach the lower layer line 3. Then, the insulating film 6 is formed in the recess of the interlayer insulating film 2. Additionally, the upper layer line 4 is formed on the insulating film 6. For example, silicon oxide, silicon nitride, or strontium titanate (SrTiO₃) having a high dielectric constant can be used for the insulating film 6.

While the insulating film 6 is formed immediately above the lower layer line 3 in FIG. 7, a certain portion of the interlayer insulating film 2 may be remained between the lower layer line 3 and the insulating film 6.

With the configuration of this exemplary embodiment, the distance between the lower layer line 3 and the upper layer line 4 can be reduced, thereby making it possible to increase the capacitance of the capacitor. Further, when a material having a dielectric constant higher than that of the interlayer insulating film 2 is used for the insulating film 6, the capacitance of the capacitor can be further increased.

In other words, assuming that a capacitance is represented by C; an area is represented by S; the thickness of a dielectric is represented by d; the dielectric constant of vacuum is represented by ε₀; and a relative dielectric constant is represented by εᵣ, C=εᵣε₀S/d is established. Thus, the thickness d can be reduced by reducing the distance between the lower layer line 3 and the upper layer line 4. Further, when a material having a high dielectric constant is used for the insulating film 6, the relative dielectric constant εᵣ can be increased. Accordingly, the configuration of this exemplary embodiment is capable of increasing the capacitance C of the capacitor.

### Fourth Exemplary Embodiment

A fourth exemplary embodiment of the present invention will be described below with reference to FIG. 8. Note that components similar to those of the first exemplary embodiment shown in FIG. 1 are denoted by the same reference numerals, and repeated description thereof is omitted.

Also in this exemplary embodiment, the insulating film 6, which is different from the interlayer insulating film 2, is used as an insulating film for forming a capacitor.

In this exemplary embodiment, after the formation of the lower layer line 3, the insulating film 6 is formed on the lower layer line 3 before the interlayer insulating film 2 is formed. In this case, silicon oxide, silicon nitride, or strontium titanate (SrTiO₃) having a high dielectric constant, for example, can be used for the insulating film 6.

After the formation of the insulating film 6, the interlayer insulating film 2 is formed. Then, a recess is formed at a location corresponding to the lower-layer electrode of the interlayer insulating film 2. In this case, the recess is formed so as to reach the insulating film 6. After that, the upper layer line 4 is filled in the recess of the interlayer insulating film 2.

While the upper layer line 4 is formed immediately above the insulating film 6 in FIG. 8, a certain portion of the interlayer insulating film 2 may be remained between the insulating film 6 and the upper layer line 4.

With the configuration of this exemplary embodiment, the distance between the lower layer line 3 and the upper layer line 4 can be reduced, thereby making it possible to increase the capacitance of the capacitor. Further, when a material having a dielectric constant higher than that of the interlayer insulating film 2 is used for the insulating film 6, the capacitance of the capacitor can be further increased.

Moreover, the second exemplary embodiment related to the width of each of the lower layer line 3 and the upper layer line 4 can also be applied to the third and fourth exemplary embodiments. That is, in the third and fourth exemplary embodiments, the width of the lower layer line 3 may be set to be greater than that of the upper layer line 4, or the width of the upper layer line 4 may be set to be greater than that of the lower layer line 3.

The first to fourth exemplary embodiments can be combined as desirable by one of ordinary skill in the art.

While the invention has been described in terms of several exemplary embodiments, those skilled in the art will recognize that the invention can be practiced with various modifications within the spirit and scope of the appended claims and the invention is not limited to the examples described above.

Further, the scope of the claims is not limited by the exemplary embodiments described above.

Furthermore, it is noted that, Applicant's intent is to encompass equivalents of all claim elements, even if amended later during prosecution.

What is claimed is:

1. A semiconductor device comprising:
a first line;
an interlayer insulating film that is formed on the first line and has a recess formed at a location corresponding to the first line; and
a second line formed in the recess of the interlayer insulating film, wherein
the first line, the second line, and an insulating film formed between the first line and the second line constitute a capacitor, and
at least one of the first line and the second line constitutes an inductor.

2. The semiconductor device according to claim 1, further comprising:
a passive element part that includes the capacitor and the inductor; and
a wiring part that includes a third line, an interlayer insulating film formed on the third line, and a fourth line formed on the interlayer insulating film,
wherein the recess is formed only in the interlayer insulating film of the passive element part.

3. The semiconductor device according to claim 1, wherein the second line is an inductor.

4. The semiconductor device according to claim 1, wherein the insulating film constituting the capacitor is the interlayer insulating film.

5. The semiconductor device according to claim 1, wherein the insulating film constituting the capacitor is an insulating film different from the interlayer insulating film.

6. The semiconductor device according to claim 1, wherein the inductor and the capacitor constitute a low-pass filter.

7. The semiconductor device according to claim 1, wherein the inductor is a spiral inductor.

8. The semiconductor device according to claim 1, wherein the width of the first line is set to be greater than the width of the recess formed in the interlayer insulating film.

9. The semiconductor device according to claim 1, wherein the width of the recess formed in the interlayer insulating film is set to be greater than the width of the first line.

10. A method of manufacturing a semiconductor device comprising:
forming a first line on a substrate;
forming an interlayer insulating film on the first line; and
forming a second line on the interlayer insulating film, wherein
the interlayer insulating film has a recess formed at a location corresponding to the first line,
the first line, the second line, and an insulating film formed between the first line and the second line constitute a capacitor, and
at least one of the first line and the second line constitutes an inductor.

11. The method of manufacturing a semiconductor device according to claim 10, wherein the insulating film constituting the capacitor is the interlayer insulating film.

12. The method of manufacturing a semiconductor device according to claim 10, wherein an insulating film which is different from the interlayer insulating film constituting the capacitor is formed on the first line.

13. The method of manufacturing a semiconductor device according to claim 10, wherein the width of the first line is set to be greater than the width of the recess formed in the interlayer insulating film.

14. The method of manufacturing a semiconductor device according to claim 10, wherein the width of the recess formed in the interlayer insulating film is set to be greater than the width of the first line.
